(19) United States
(12) Patent Application Publication
(10) Pub. No.: US 2026/0047186 A1
(43) Pub. Date: Feb. 12, 2026

(54) SEMICONDUCTOR DEVICE WITH RESISTIVE ELEMENTS

(71) Applicant: Taiwan Semiconductor Manufacturing Company, Ltd., Hsinchu (TW)

(72) Inventors: Ying-Han Chiou, Tainan City (TW); Bo-Huan Hsin, Taichung City (TW)

(21) Appl. No.: 18/798,511

(22) Filed: Aug. 8, 2024

(51) Int. Cl. H01L 27/06; H01L 23/522; H01L 29/06; H01L 29/423; H01L 29/66; H01L 29/775; H01L 29/786

(52) U.S. Cl. CPC H10D 84/811; H01L 23/5228; H10D 1/474; H10D 64/017; H10D 30/43; H10D 30/6735; H10D 30/6757; H10D 62/121

(57) ABSTRACT

A semiconductor structure having a resistive element includes a substrate having an active region, a first gate structure formed over the active region, and a first resistive element formed over the active region and adjacent to the first gate structure. In some embodiments, the first resistive element includes a first resistive layer and a second resistive layer formed over the first resistive layer. In some examples, a total resistance of the first resistive element is a combination of resistances of the first and second resistive layers.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. As a result, the challenge of fabricating reliable electronic devices has increased.

Thus, the realization of continued advances in semiconductor ICs and devices calls for similar advances in semiconductor manufacturing processes and technology. However, existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, according to some embodiments;

FIG. 2 provides a cross-sectional view of a semiconductor device, including a resistive element, along a plane substantially parallel to a plane defined by section XX′ of FIG. 1, according to some embodiments;

FIG. 3 provides a cross-sectional view of the resistive element, along a plane substantially parallel to a plane defined by section YY′ of FIG. 1, according to some embodiments;

FIG. 4A provides a perspective view of the resistive element, along the plane substantially parallel to the plane defined by section YY′ of FIG. 1, according to some embodiments;

FIG. 4B and FIG. 4C provide top down views of the resistive element, according to some embodiments;

FIG. 5 provides a cross-sectional view of a semiconductor device similar to the example of FIG. 2, but having a different configuration, according to some embodiments;

FIG. 6 provides a cross-sectional view of a semiconductor device similar to the example of FIG. 2, but having another different configuration, according to some embodiments;

FIG. 7 provides a cross-sectional view of a semiconductor device similar to the example of FIG. 2, but having still another different configuration, according to some embodiments;

FIG. 8 provides a cross-sectional view of a resistive element formed at an active edge, along a plane substantially parallel to a plane defined by section YY′ of FIG. 1, according to some embodiments;

FIG. 9 and FIG. 10 provide cross-sectional views of the resistive element similar to those shown in FIG. 3 and FIG. 8, respectively, but with different thicknesses of constituent layers of the resistive element, according to some embodiments;

FIG. 11 provides a cross-sectional view of a resistive element and a simplified circuit schematic of the resistive element, according to some embodiments; and

FIG. 12 is a flow chart of a method of forming a resistive element as part of a MEOL and/or FEOL process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally directed to a semiconductor structure including a resistive element, where the resistive element functions as a resistor. In some cases, the resistive element may be formed as part of a middle-end-of line (MEOL) and/or as part of a front-end-of-line (FEOL) process. The resistive elements disclosed herein may further be electrically connected to other MEOL/FEOL features and/or to a back-end-of-line (BEOL) multilayer metal interconnect structure to form integrated circuits including the resistive elements. In some examples, the resistive elements disclosed herein may be formed as part of an analog and/or digital circuit. However, the disclosed resistive elements may be generally applicable to any type of circuit using resistors.

It is also noted that the present disclosure presents embodiments in the form of a resistive element which may be employed in any of a variety of device types. For example, embodiments of the present disclosure may be used to form resistive elements in multi-gate devices which may include a P-type metal-oxide-semiconductor device or an N-type metal-oxide-semiconductor multi-gate device. Specific examples may be presented and referred to herein as fin field-effect transistors (FinFETs), on account of their fin-like structure. FinFET devices may include fins extending from a substrate (or nanostructures extending from a substrate), where the fins are composed of a substantially uniform composition. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in various nanostructures such as nanosheet channel(s), nanowire channel(s), bar-shaped channel(s), and/or other suitable channel configurations. Presented herein are embodiments of devices that may have one or more nanostructured channel regions (e.g., nanowires/nanosheets) associated with a single, contiguous gate structure. GAA devices may include a plurality of stacked channel layers (e.g., a plurality of stacked nanosheets) that form the channels of a GAA transistor. One of ordinary skill would recognize that the teachings disclosed herein can apply to a single channel (e.g., single nanowire/nanosheet) or any number of channels. One of ordinary skill may recognize other examples of semiconductor devices that may benefit from aspects of the present disclosure. For example, in some cases, aspects of the present disclosure may be equally applicable to planar transistor devices, fork sheet devices, complementary FET (CFET) devices, and the like. CFET devices include a first transistor of a first conductivity type (e.g., n-type or p-type) vertically stacked over a second transistor having an opposite conductivity type. In some examples, GAA transistors may be used to implement CFET devices. One of ordinary skill may recognize other embodiments of semiconductor devices that may benefit from aspects of the present disclosure.

Embodiments of the present disclosure offer advantages over the existing art, though it is understood that other embodiments may offer different advantages, not all advantages are necessarily discussed herein, and no particular advantage is required for all embodiments. As previously noted, embodiments discussed herein include semiconductor structures having a resistive element, where the resistive element is formed as part of a MEOL and/or FEOL process. In at least some existing implementations, resistive elements are formed as part of a BEOL process, for example, between metal layers of a multilayer metal interconnect structure. Formation of resistive elements in the BEOL requires the use of valuable chip area that can be otherwise used for other features such as portions of the BEOL multilayer metal interconnect structure, as well as other devices such as capacitors, inductors, fuses, memory devices, etc. In addition, resistive elements formed in the BEOL multilayer metal interconnect structure are disposed further away from FEOL devices (e.g., transistors), thereby increasing resistance and signal delay. In contrast, and in accordance with embodiments of the present disclosure, by forming the resistive element as part of a MEOL and/or FEOL process, the shortcomings discussed above can be effectively addressed. For instance, formation of resistive elements in the MEOL and/or FEOL reduces consumption of valuable chip area, particularly in the BEOL, and reduces associated processing costs. Further, resistive elements formed in the MEOL and/or FEOL are disposed closer to FEOL devices (e.g., transistors), thereby decreasing resistance, decreasing signal delay, and enhancing device performance. Additional details of embodiments of the present disclosure are provided below, and additional benefits and/or other advantages will become apparent to those skilled in the art having benefit of the present disclosure.

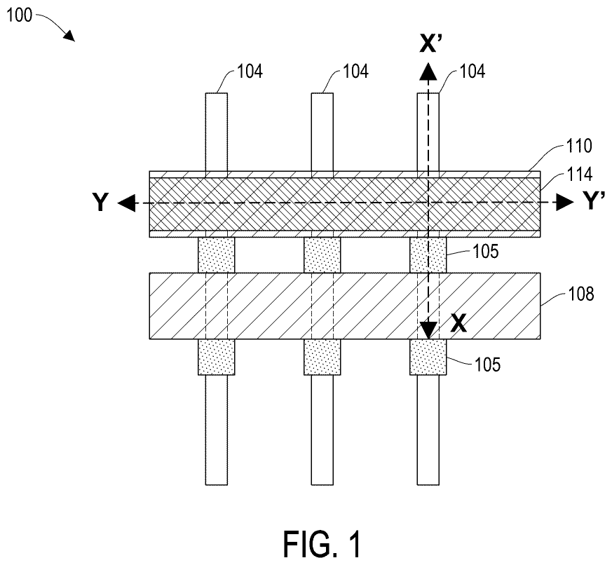

As discussed above, embodiments of the present disclosure may be applicable to various types of devices such as planar transistor devices, FinFET devices, GAA devices including a plurality of nanosheet channel layers, forksheet devices, CFET devices having a first transistor of a first conductivity type (e.g., n-type or p-type) vertically stacked over a second transistor having an opposite conductivity type, and others. However, for clarity of discussion, aspects of the disclosed embodiments will be discussed with reference to an exemplary multi-gate device, such as shown and described below. By way of example, FIG. 1 provides a simplified top-down layout view of a multi-gate device 100. While not limited thereto, for purposes of this discussion the multi-gate device 100 may include a FinFET device. As such, in some embodiments, the multi-gate device 100 may include a plurality of fin elements 104 of substantially uniform composition extending from a substrate, gate structures 108, 110 disposed over and around the fin elements 104, source/drain features 105 (e.g., formed in, on, and/or surrounding the fins 104). To be sure, in some cases, the multi-gate device 100 may include a GAA device and the fin elements 104 may include a plurality of nanosheets that are used to provide the channels in a GAA device. As noted above, GAA devices may further be used to implement CFET devices. Thus, the various embodiments disclosed herein may be equally applicable to FinFET devices, GAA devices, CFET devices, or other semiconductor devices.

In some cases, the gate structures 108, 110 may both initially include a dummy gate structure having a suitable dummy gate material, such as polysilicon. At a later stage of processing of the multi-gate device 100, the dummy gate structure (of the gate structure 108) may be replaced by a high-K metal gate stack, and the dummy gate structure (of the gate structure 110) may be at least partially replaced by a resistive element 114. Stated another way, the resistive element 114 is at least partially overlapping the dummy gate structure (of the gate structure 110). Channel regions of the multi-gate device 100, or of the FinFET device, are disposed within the fins 104, underlying the gate structure 108, along a plane substantially parallel to a plane defined by section XX′ of FIG. 1. In some embodiments, sidewall spacers may also be formed on sidewalls of the gate structures 108, 110. While some examples of the configuration of the resistive element 114 have been given, it will be understood that other configurations are possible, while remaining within the scope of the present disclosure, as discussed in more detail below.

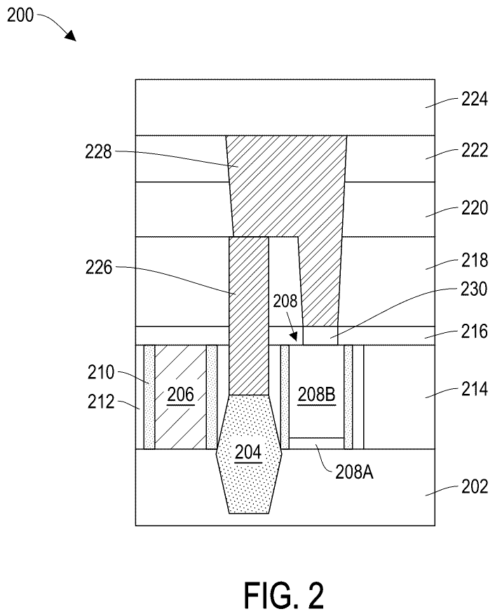

Referring now to FIG. 2, illustrated therein is an exemplary semiconductor device 200 including a resistive element, in accordance with some embodiments of the present disclosure. In some embodiments, the semiconductor device 200 may include the multi-gate device 100, described above. Thus, one or more aspects discussed above with reference to the multi-gate device 100 may also apply to the semiconductor device 200. In particular, FIG. 2 provides a cross-sectional view of the semiconductor device 200 along a plane substantially parallel to a plane defined by section XX′ of FIG. 1.

As shown, the semiconductor device 200 includes a substrate with an active region 202 having a fin element extending from the substrate. In some embodiments, the fin element may be similar to the fin elements 104, described above. The substrate, from which the fin element extends, may be a semiconductor substrate such as a silicon substrate. The substrate may include various layers, including conductive or insulating layers formed on the substrate. The substrate may include various doping configurations depending on design requirements as is known in the art. The substrate may also include other semiconductors such as germanium, silicon carbide (SiC), silicon germanium (SiGe), or diamond. Alternatively, the substrate may include a compound semiconductor and/or an alloy semiconductor. Further, in some embodiments, the substrate may include an epitaxial layer (epi-layer), the substrate may be strained for performance enhancement, the substrate may include a silicon-on-insulator (SOI) structure, and/or the substrate may have other suitable enhancement features.

The fin element, like the substrate, may include one or more epitaxially-grown layers, and may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, InGaAs, GalnP, and/or GaInAsP; or combinations thereof. The fin element may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate while an etch process forms recesses into the silicon layer, thereby leaving an extending fin element. The recesses may be etched using a dry etch (e.g., chemical oxide removal), a wet etch, and/or other suitable processes. Numerous other embodiments of methods to form fin elements extending from a substrate may also be used.

The semiconductor device 200 also includes isolation regions, such as shallow trench isolation (STI) features, to provide isolation between active regions. Alternatively, a field oxide, a LOCOS feature, and/or other suitable isolation features may be implemented on and/or within the substrate from which the fin element extends. The isolation regions may be composed of silicon oxide, silicon nitride, silicon oxynitride, fluorine-doped silicate glass (FSG), a low-k dielectric, combinations thereof, and/or other suitable material known in the art. In an embodiment, the isolation regions are STI features and are formed by etching trenches in the substrate. The trenches may then be filled with isolating material, followed by a chemical mechanical polishing (CMP) process. However, other embodiments are possible. In some embodiments, the isolation regions may include a multi-layer structure, for example, having one or more liner layers.

The semiconductor device 200 further includes a source/drain feature 204 (like the source/drain features 105) formed in, on, and/or surrounding the fin element. The source/drain feature 204 may be epitaxially grown over the fin element. As shown, the semiconductor device 200 also includes a gate structure 206 and a resistive element 208. In various other embodiments, fewer or more source/drain features may be provided, for example, on opposing sides of one or both of the gate structure 206 and the resistive element 208. The source/drain feature 204 may correspond to a transistor (such as a FinFET device), disposed on a first side of the resistive element 208 and having the gate structure 206 as the transistor gate. It is noted that, in various embodiments and prior to forming the gate structure 206 and the resistive element 208, regions of the semiconductor device 200 where the gate structure 206 and the resistive element 208 are to be formed may be initially occupied by a dummy gate structure including a dummy gate dielectric and a dummy gate electrode (e.g., such as a polysilicon gate). At a later stage of processing, a first one of the dummy gate structures may be removed and replaced by the gate structure 206, having the various features described below. Similarly, at a later stage of processing, a second one of the dummy gate structures may be removed and replaced by the resistive element 208, having the various features described below.

The gate structure 206, formed after removal of a dummy gate dielectric and a dummy gate electrode, may include a high-K/metal gate structure having an interfacial layer formed over the fin element, a gate dielectric layer formed over the interfacial layer, and a metal gate (MG) layer formed over the gate dielectric layer. In some embodiments, the interfacial layer includes a silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric layer includes a high-K dielectric layer such as hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTIO, (Ba,Sr) TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). In still other embodiments, the gate dielectric layer may include silicon dioxide or other suitable dielectric. The gate dielectric layer may be formed by ALD, physical vapor deposition (PVD), CVD, oxidation, and/or other suitable methods. In some embodiments, the MG layer may be deposited as part of a gate first or gate last (e.g., replacement gate) process. In various embodiments, the MG layer includes a conductive layer such as W, Ti, TiN, TiAl, TiAlN, Ta, TaN, WN, Re, Ir, Ru, Mo, Al, Cu, Co, CoSi, Ni, NiSi, combinations thereof, and/or other suitable compositions. In some examples, the MG layer may include a first metal material for an N-type transistor and a second metal material for a P-type transistor. Thus, the semiconductor device 200 may include a dual work-function metal gate configuration. For example, the first metal material (e.g., for N-type devices) may include metals having a work function substantially aligned with a work function of the substrate conduction band, or at least substantially aligned with a work function of the conduction band of a channel region of the semiconductor device 200. Similarly, the second metal material (e.g., for P-type devices) may include metals having a work function substantially aligned with a work function of the substrate valence band, or at least substantially aligned with a work function of the valence band of the channel region of the semiconductor device 200. Thus, the MG layer may provide a gate electrode for the semiconductor device 200, including both N-type and P-type devices. In some embodiments, the gate electrode may alternately or additionally include a polysilicon layer. In various examples, the gate electrode may be formed using PVD, CVD, electron beam (e-beam) evaporation, and/or other suitable process.

The resistive element 208, formed after removal of a dummy gate dielectric and a dummy gate electrode, may include a first resistive layer 208A formed over the fin element and a second resistive layer 208B over the first resistive layer 208A. In some embodiments, the first resistive layer 208A includes TiN, related oxides such as TiOₓ or TiNOₓ, or combinations thereof. Thus, for example and in various embodiments, the first resistive layer 208A may include a single layer of TiN, a single oxide layer such as TiOₓ or TiNOₓ, or a stack of layers such as TiN/TiOₓ or TiN/TiNOₓ, as well as other combinations thereof. In some embodiments, the second resistive layer 208B includes crystalline silicon (Si), amorphous Si (a-Si), SiOₓ, a-SiOₓ, or combinations thereof. Thus, for example and in various embodiments, the second resistive layer 208B may include a single layer of Si, a single layer of a-Si, a single layer of SiOₓ, a single layer of a-SiOₓ, or a stack of layers such as Si/SiOₓ, a-Si/a-SiOₓ, as well as other combinations thereof. In some cases, either one or both of the first and second resistive layers 208A, 208B may include TiN, Ta, TaN, or a nickel complex (NiCR), as well as oxides such as TiₓO_{y}, TaₓO_{y}, CuₓO_{y}, AlₓO_{y} (where x and y are integer values), or a combination thereof. Generally, each of the first and second resistive layers 208A, 208B include a high resistance material, and the first and second resistive layers 208A, 208B collectively form a high resistance device (resistor), as described in more detail below. In some embodiments, a total resistance of the high resistance device is in a range of about 300-1,500 Ohms/μm².

In some embodiments, the gate structure 206 and the resistive element 208 may include sidewall spacer layers 210, 212 (e.g., that were formed on sidewalls of respective dummy gate structures prior to removal of the dummy gate structures and replacement by the gate structure 206 and the resistive element 208). In some cases, each of the sidewall spacer layers 210, 212 include materials having different dielectric constant values (e.g., K values). In various embodiments, the sidewall spacer layers 210, 212 include dielectric materials such as silicon oxide, silicon nitride, silicon carbide, silicon oxynitride, or combinations thereof. In some embodiments, the sidewall spacer layers 210, 212 include multiple layers, such as main spacer walls, liner layers, and the like. By way of example, the sidewall spacer layers 210, 212 may be formed by depositing a dielectric material over the semiconductor device 200 and anisotropically etching back the dielectric material. In some embodiments, the etch-back process (e.g., for sidewall spacer formation) may include a multiple-step etching process to improve etch selectivity and provide over-etch control.

Still referring to FIG. 2, the semiconductor device 200 further includes a dielectric layer 214 is formed over the substrate, including over the fin element. By way of example, the dielectric layer 214 may include first inter-layer dielectric (ILD0) layer that may include materials such as tetraethylorthosilicate (TEOS) oxide, un-doped silicate glass, or doped silicon oxide such as borophosphosilicate glass (BPSG), fluorine-doped silicate glass (FSG), phosphosilicate glass (PSG), boron doped silicon glass (BSG), and/or other suitable dielectric materials. The dielectric layer 214 may be deposited by a subatmospheric CVD (SACVD) process, a flowable CVD process, or other suitable deposition technique. In some embodiments, a nitride layer 216 may be formed over the semiconductor device 200, including over the gate structure 206, the resistive element 208, the sidewall spacer layers 210, 212, and the dielectric layer 214. The nitride layer 216 may, in some cases, include a silicon nitride layer (SiN), although other embodiments are possible. In various embodiments, the nitride layer 216 may be deposited by a SACVD process, a flowable CVD process, an ALD process, a PVD process, or other suitable deposition technique. In various examples, a dielectric layer 218 is formed over the nitride layer 216. By way of example, the dielectric layer 218 may include a second inter-layer dielectric (ILD1) layer that may include similar materials to those described above with reference to the dielectric layer 214. The dielectric layer 218 may thus also be deposited by a SACVD process, a flowable CVD process, or other suitable deposition technique. In various examples, after deposition of one or more of the layers described herein, such as the dielectric layer 214, the nitride layer 216, or the dielectric layer 218, a chemical mechanical planarization (CMP) process may be performed to remove excess material and planarize the top surface of the semiconductor device 200.

In some embodiments, the semiconductor device 200 further includes a metal layer 226 that provides contact to the source/drain feature 204. Initially, and in some embodiments, an opening is formed within portions of the dielectric layer 214, the nitride layer 216, and the dielectric layer 218 disposed over the source/drain feature 204 to provide access to the source/drain feature 204. By way of example, such an opening may be formed by a suitable combination of lithographic patterning and etching (e.g., wet or dry etching) processes. After forming the opening, and in some embodiments, a silicidation process may be performed to form a silicide layer on the portion of the source/drain feature 204 exposed by the opening, thus providing a low resistance contact thereto. In some examples, a glue or barrier layer may be formed within the opening prior to formation of the metal layer 226. In some cases, the glue or barrier layer may include Ti, TiN, Ta, TaN, W, or other appropriate material. In some examples, the metal layer 226 may include W, Cu, Co, Ru, Al, Rh, Mo, Ta, Ti, TiN, TaN, WN, or other suitable conductive material. After deposition of the metal layer 226, a CMP process may be performed to remove excess material and planarize the top surface of the semiconductor device 800.

Still referring to FIG. 2, the semiconductor device 200 further includes a contact etch stop layer (CESL) 220 formed over the substrate, including over the dielectric layer 218 and the metal layer 226. In addition, a dielectric layer 222 is formed over the contact etch stop layer 220. By way of example, the contact etch stop layer 220 may include Ti, TiN, TIC, TiCN, Ta, TaN, TaC, TaCN, W, WN, WC, WCN, TiAl, TIAIN, TiAIC, TIAICN, or combinations thereof. In some embodiments, the dielectric layer 222 may include an inter-layer dielectric (ILD2) layer that may include similar materials to those described above with reference to the dielectric layer 214. In various embodiments, the CESL 220 and the dielectric layer 222 may be deposited by a SACVD process, a flowable CVD process, an ALD process, a PVD process, or other suitable deposition technique.

In some embodiments, the semiconductor device 200 further includes a metal layer 228 that provides contact to the resistive element 208 and to the metal layer 226 (and thus to the source/drain feature 204). In some cases, an adhesion layer 230 may also be formed interposing the metal layer 228 and the resistive element 208 to enhance adhesion of the metal layer 226. In at least some examples, the adhesion layer 230 may include a silicide layer. Initially, and in some embodiments, an opening (or multiple overlapping openings) are formed within portions of the dielectric layer 222, the contact etch stop layer 220, the dielectric layer 218, and the nitride layer 216 disposed over the resistive element 208 to provide access to the resistive element 208 and to the metal layer 226. By way of example, such an opening (or openings) may be formed by a suitable combination of lithographic patterning and etching (e.g., wet or dry etching) processes. After forming the opening (or openings), and in some embodiments, the adhesion layer 230 may be formed. In addition, and in some cases, a glue or barrier layer may be formed within the opening (or openings) prior to formation of the metal layer 228. In some cases, the glue or barrier layer may include Ti, TiN, Ta, TaN, W, or other appropriate material. In some examples, the metal layer 228 may include W, Cu, Co, Ru, Al, Rh, Mo, Ta, Ti, or other conductive material. After deposition of the metal layer 228, a CMP process may be performed to remove excess material and planarize the top surface of the semiconductor device 200. Thus, after deposition of the metal layer 228, contact is made between the resistive element 208 and the adjacent source/drain feature 204. In some cases, the metal layer 228 may be referred to as a via rail (VDR), or as an interconnect feature, that may be used to connect a plurality of features to a power supply. It is noted that in at least some embodiments, the metal layer 226 (in contact with the source/drain feature 204) and the metal layer 228 (in contact with the resistive element 208) are composed of different materials. For example, in an embodiment, the metal layer 226 includes cobalt (Co) and the metal layer 228 includes tungsten (W). Additionally, in some embodiments, the metal layer 226 and the metal layer 228 may be composed of the same material. A BEOL layer 224, which includes at least a portion of a multilayer metal interconnect structure formed as part of a BEOL process, is disposed over the metal layer 228 and the dielectric layer 222. In some embodiments, the metal layer 228 may further connect to the portion of the multilayer metal interconnect structure in the BEOL layer 224 to provide additional connections to other devices and/or structures on the substrate.

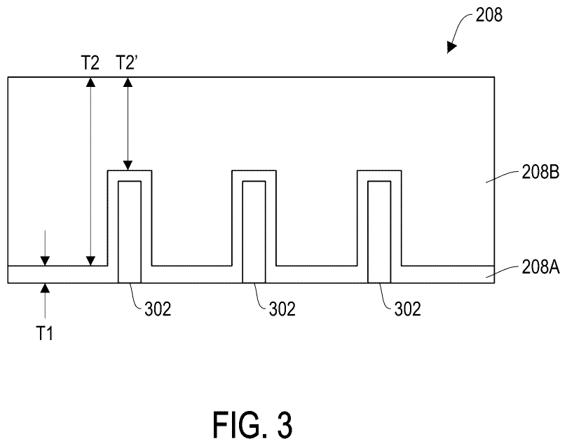

Referring now to FIG. 3, illustrated therein is a cross-sectional view of the resistive element 208, along a plane substantially parallel to a plane defined by section YY′ of FIG. 1. As shown, the resistive element 208, which in this example is formed in the active region 202, may be disposed over multiple fin elements 302 extending from the substrate. As discussed above, the resistive element 208 includes the first resistive layer 208A and the second resistive layer 208B over the first resistive layer 208A. In some embodiments, the first resistive layer 208A may have a thickness T1 in a range of between about 0.1 nm-10 nm. Thus, in some examples, the first resistive layer 208A may be described as having a sheet structure. In contrast, the second resistive layer 208B may have a thickness T2 and a thickness T2′ (over a fin element 302) less than the thickness T2. In some embodiments, a total thickness (or height) of the resistive element 208 may be about 14 nm, or in a range of between about 12-16 nm. It is noted that a total resistance of the resistive element 208 is a combination of the resistance of the first resistive layer 208A and the second resistive layer 208B. In some embodiments, and as described in more detail below, the total resistance of the resistive element 208 may be a parallel combination of the resistances of each of the first resistive layer 208A and the second resistive layer 208B.

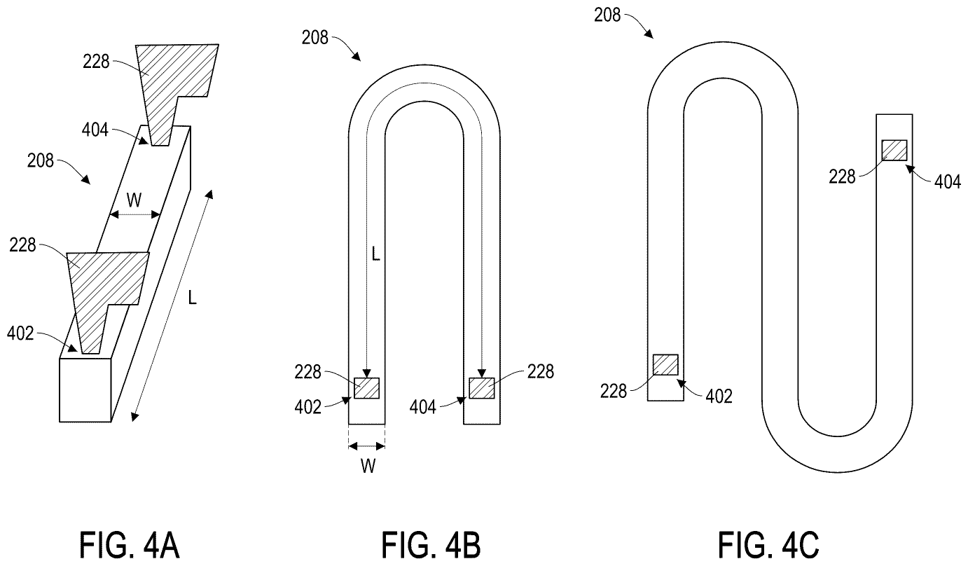

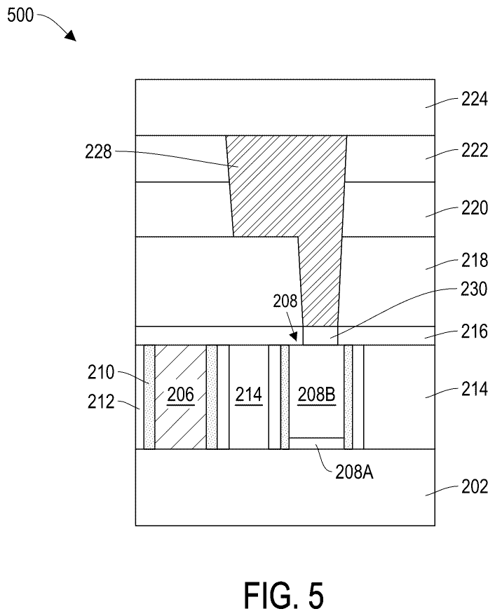

FIG. 4A provides a perspective view of the resistive element 208, along the plane substantially parallel to the plane defined by section YY′ of FIG. 1. In contrast to the example of FIG. 3, the example of FIG. 4A does not show the multiple fin elements 302 but does include an illustration of multiple portions of the metal layer 228 that are used to provide first and second electrical contacts 402, 404 at opposing ends of the resistive element 208, as shown. In the example of FIG. 4A, the resistive element 208 may be generally described as having a linear rectangular prism shape connected at opposing ends to the first and second electrical contacts 402, 404. In some alternative embodiments, and with reference to FIG. 4B and FIG. 4C, illustrated therein are top down views of the resistive element 208 showing that the resistive element 208 may have a curved or S-shaped structure. Stated another way, the resistive element 208 may have a curved rectangular prism shape or an S-shaped rectangular prism shape, and in various examples may have one or a plurality of curves (or turns). In the example of FIG. 4B, the resistive element 208 has a single curve (or single turn), and in the example of FIG. 4C, the resistive element 208 has multiple curves (or multiple turns). Like the example of FIG. 4A, FIGS. 4B/4C show multiple portions of the metal layer 228 that are used to provide the first and second electrical contacts 402, 404 at opposing ends of the resistive element 208. Regardless of the particular shape (e.g., linear rectangular prism, curved rectangular prism or S-shaped rectangular prism), in various embodiments, the resistive element 208 may have a total length L (e.g., as measured between the first and second electrical contacts 402, 404) up to 100 microns. More generally, the resistive element 208 may have a total length L in a range of between about 20-2,000 μm. In addition, and in some examples, the resistive element 208 may have a width W in a range of between about 6-135 nm.

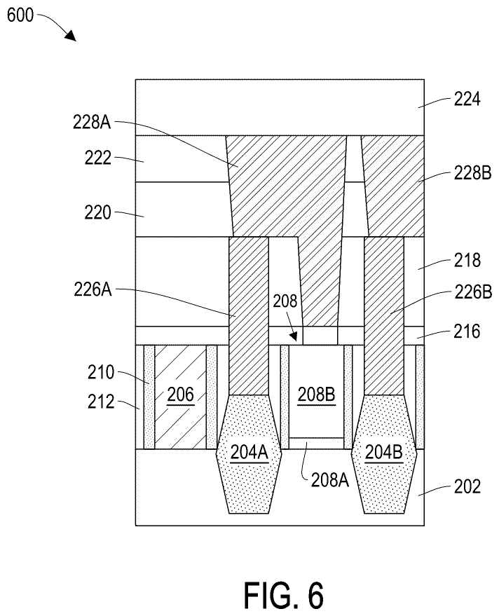

In the example of FIG. 2, discussed above, the semiconductor device 200 is illustrated as having the source/drain feature 204 on one side of the resistive element 208 (e.g., between the resistive element 208 and the adjacent gate structure 206). However, as previously noted, fewer or more source/drain features may be provided on opposing sides of one or both of the gate structure 206 and the resistive element 208. For example, referring to FIG. 5, illustrated therein is an exemplary semiconductor device 500 including a resistive element, but having a different configuration of source/drain features as compared to the example of FIG. 2. In particular, in the example of FIG. 5, the resistive element 208 is free of source/drain features on either side of the resistive element 208. As shown, the sidewall spacers 210, 212 are disposed on opposing sides of the resistive element 208, and the dielectric layer 214 is formed in contact with the sidewall spacers (the sidewall spacer 212) on either side of the resistive element 208. Stated another way, rather than having the source/drain feature 204 between the resistive element 208 and the adjacent gate structure 206, the example of FIG. 5 illustrates having the dielectric layer 214 between the resistive element 208 and the adjacent gate structure 206.

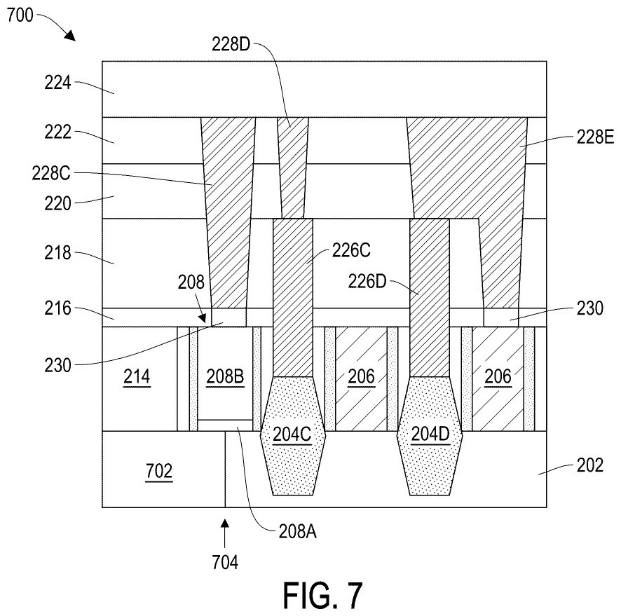

In another example, and with reference to FIG. 6, illustrated therein is an exemplary semiconductor device 600 including a resistive element, but having a different configuration of source/drain features as compared to the examples of FIG. 2 and FIG. 5. In particular, in the example of FIG. 6, the resistive element 208 includes source/drain features on both sides (on opposing sides) of the resistive element 208. As shown, a first source/drain feature 204A (which may be the source/drain feature 204, discussed above) is disposed on a first side of the resistive element 208 between the resistive element 208 and the adjacent gate structure 206. Further, a second source/drain feature 204B is disposed on a second side of the resistive element 208 between the resistive element 208 and optionally another adjacent gate structure (not shown). In some embodiments, the source/drain feature 204A may correspond to a first transistor (such as a FinFET device), disposed on a first side of the resistive element 208 and having the gate structure 206 as the transistor gate, and the source/drain feature 204B may correspond to a second transistor (such as a FinFET device), disposed on a second side of the resistive element 208 and having another gate structure (not shown) as the transistor gate. As also shown in the example of FIG. 6, the semiconductor device 600 includes a metal layer 226A and a metal layer 228A (which may be the metal layers 226 and 228, discussed above) that provide contact to the resistive element 208 and to the metal layer 226A (and thus to the source/drain feature 204A). In some embodiments, the semiconductor device 600 further includes a metal layer 226B (like the metal layer 226A) and a metal layer 228B (like the metal layer 228A) over the metal layer 226B that provide contact to the source/drain feature 204B.

In the examples discussed above, the resistive element 208 is described as being formed in the active region 202 that may include one or more fin elements (e.g., such as the fin elements 302 shown in FIG. 3). However, in at least some examples, the resistive element 208 may be formed along an active edge (or a diffusion edge), which is defined along a boundary of an active region and which is free of fin elements. In particular, as isolation regions (e.g., such as STI features) may be used to provide isolation between active regions, an active edge may in some examples be defined along a boundary between an active region and an isolation region.

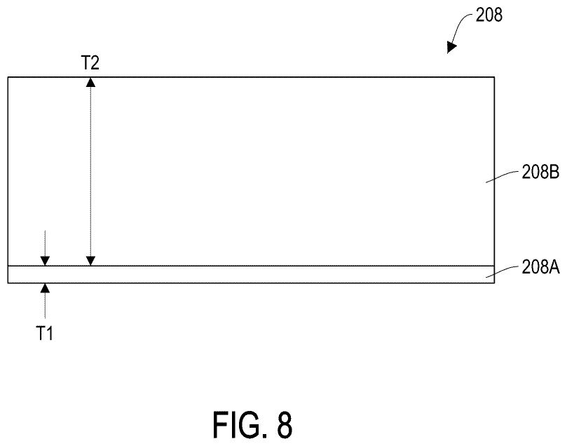

Referring now to FIG. 7, illustrated therein is exemplary semiconductor device 700 including a resistive element formed along an active edge. As shown, the semiconductor device 700 includes the active region 202 including one or more fin elements, an isolation region 702 (e.g., such as an STI feature), and an active edge 704 defined at the boundary between the active region 202 and the isolation region 702. In some embodiments, a resistive element 208 is formed along the active edge 704. Like the examples discussed above, prior to forming the resistive element 208 along the active edge 704, a dummy gate structure including a dummy gate dielectric and a dummy gate electrode (e.g., such as a polysilicon gate) is initially disposed along the active edge 704. At a later stage of processing, the dummy gate structure along the active edge 704 is removed and replaced by the resistive element 208, as previously discussed. The resistive element 208 may thus overlap the active region 202 and the isolation region 702, as shown. The dielectric layer 214 (ILD0) may also be formed adjacent to the resistive element 208 and over the isolation region 702.

As also shown in the example of FIG. 7, the semiconductor device 700 includes metal layers 226C and 226D (which may be the metal layer 226, discussed above) that provide contact to source/drain features 204C and 204D, respectively. The semiconductor device 700 may further include metal layers 228C, 228D, and 228E (which may be the metal layer 228, discussed above). The metal layer 228C provides contact to the resistive element 208, with the adhesion layer 230 optionally disposed therebetween. In some embodiments, the metal layer 228D provides contact to the metal layer 226C (and thus to the source/drain feature 204C), and the metal layer 228E provides contact to the metal layer 226D (and thus to the source/drain feature 204D) and to an adjacent gate structure 206. In some embodiments, the adhesion layer 230 is optionally disposed between the metal layer 228E and the adjacent gate structure 206.

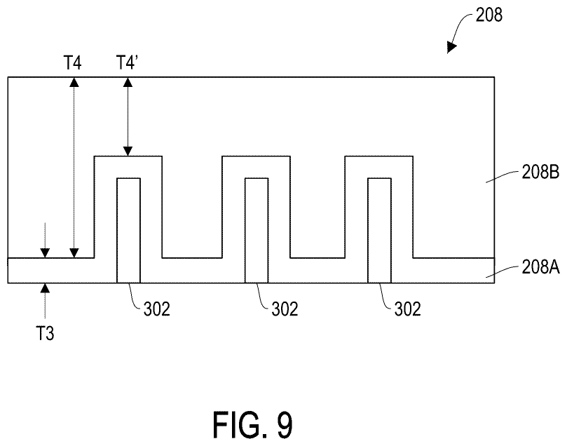

Referring now to FIG. 8, illustrated therein is a cross-sectional view of the resistive element 208 formed along an active edge (e.g., such as the active edge 704), along a plane substantially parallel to a plane defined by section YY′ of FIG. 1. As shown in FIG. 8, the resistive element 208, which in this example is formed along an active edge, is free of fin elements in contrast to the example of FIG. 3, discussed above. As previously noted, the resistive element 208 includes the first resistive layer 208A and the second resistive layer 208B over the first resistive layer 208A. In some embodiments, the first resistive layer 208A may have a thickness T1 in a range of between about 0.1 nm-10 nm. Thus, in some examples, the first resistive layer 208A may be described as having a sheet structure. In some embodiments, a total thickness (or height) of the resistive element 208 may be about 14 nm, or in a range of between about 12-16 nm. Moreover, because of the absence of fin elements, each of the first and second resistive layers 208A, 208B have substantially uniform thicknesses along the length of the resistive element 208. A total resistance of the resistive element 208 is a combination of the resistance of the first resistive layer 208A and the second resistive layer 208B, where the total resistance of the resistive element 208 may be a parallel combination of the resistances of each of the first resistive layer 208A and the second resistive layer 208B. Moreover, due to the lack of fin elements in the resistive element 208 and the substantially uniform thicknesses of the first and second resistive layers 208A, 208B, in this example, the resistance along the length of the resistive element 208 may be substantially uniform.

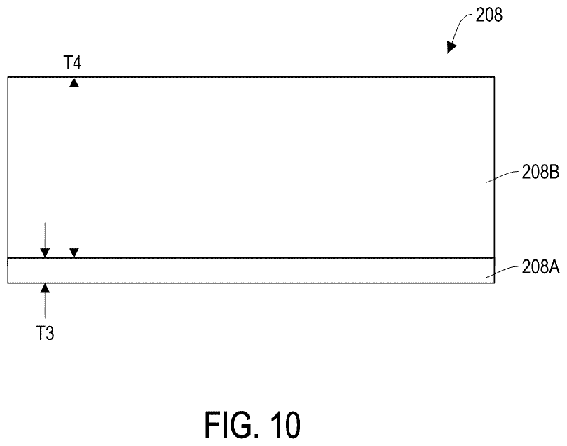

FIGS. 9 and 10 illustrate embodiments of the resistive element 208 having varying thicknesses of the first and second resistive layers 208A, 208B in order to provide resistive elements 208 with different total resistance, as compared to the examples previously described. FIG. 9 is substantially the same as FIG. 3, where the resistive element is formed in the active region 202 and is disposed over fin elements 302. However, in the example of FIG. 9, the first resistive layer 208A may have a greater thickness T3 (as compared to T1), and the second resistive layer 208B may have a lesser thickness T4 (as compared to T2) and a lesser thickness T4′ (as compared to T2′, over the fin element 302) due to the increased thickness T3 of the first resistive layer 208A. Due to the varied thicknesses of each of the first and second resistive layers 208A, 208B, the resistances of the layers may be expected to change. Further, the total resistance of the resistive element 208 of FIG. 9, which is a combination of the resistance of the first resistive layer 208A and the second resistive layer 208B, will be different than the total resistance of the resistive element 208 of FIG. 3.

Similarly, FIG. 10 is substantially the same as FIG. 8, where the resistive element is formed along an active edge and is free of fin elements. However, in the example of FIG. 10, the first resistive layer 208A may have the greater thickness T3 (as compared to T1), and the second resistive layer 208B may have a lesser thickness T4 (as compared to T2) due to the increased thickness T3 of the first resistive layer 208A. Once again, due to the varied thicknesses of each of the first and second resistive layers 208A, 208B, the resistances of the layers may be expected to change. Further, the total resistance of the resistive element 208 of FIG. 10, which is a combination of the resistance of the first resistive layer 208A and the second resistive layer 208B, will be different than the total resistance of the resistive element 208 of FIG. 8.

In view of the above discussion, it follows that a plurality of resistive elements 208, having a variety of resistance values, may be provided within a given semiconductor device or integrated circuit by tuning the thicknesses of one or both of the first and second resistive layers 208A, 208B for respective ones of the plurality of resistive elements 208. Stated another way, a single circuit or semiconductor device may include a plurality of resistive elements 208 which have a variety of different resistance values. As merely one example, in a given semiconductor device or integrated circuit, a first resistive element 208 may have a first resistive layer 208A composed of TiN having a first thickness, and a second resistive element 208 may have a second resistive layer 208A composed of TiN having a second thickness different than the first thickness. As a result, the resistance of the first and second resistive elements 208 is different, and the respective resistive elements 208 may be used for different purposes within the given semiconductor device or integrated circuit. For avoidance of doubt, it will also be understood that a given semiconductor device or integrated circuit may also include resistive elements 208 formed in one or both of an active region (e.g., as in FIGS. 3, 9) and an active edge (e.g., as in FIG. 8, 10).

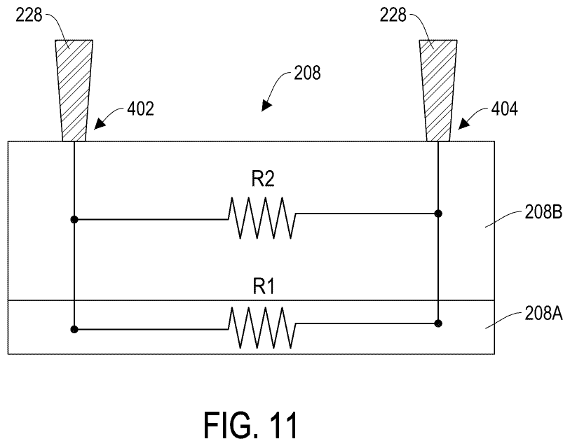

As previously noted, the total resistance of the resistive element 208 may be a parallel combination of the resistances of each of the first resistive layer 208A and the second resistive layer 208B. For purposes of illustration, and with reference to FIG. 11, provided therein is an embodiment of a resistive element 208 (e.g., similar to the embodiments of FIGS. 8, 10) including portions of the metal layer 228 that are used to provide the first and second electrical contacts 402, 404 at opposing ends of the resistive element 208. In particular, the example of FIG. 11 also illustrates a simplified circuit schematic including a first resistor R1 (corresponding to the first resistive layer 208A) and a second resistor R2 (corresponding to the second resistive layer 208B). As shown, the first and second resistors R1, R2 are connected in parallel, and are also connected to each of the first and second electrical contacts 402, 404. By varying thicknesses of one or both of the first and second resistive layers 208A, 208B, the resistance of the first and second resistors R1, R2, and thus the total resistance of the resistive element 208, may be varied. It will be understood that a similar circuit schematic including parallel resistors R1, R2 may be applied to embodiments of resistive elements 208 such as shown and discussed with reference to FIGS. 3 and 9.

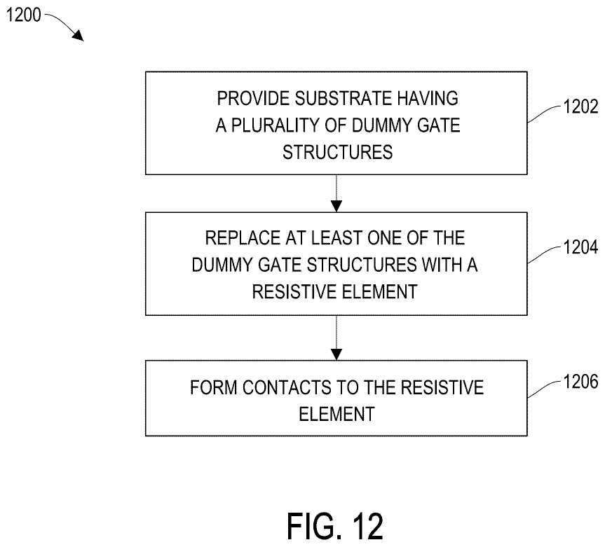

Referring now to FIG. 12, illustrated is a method 1200 of forming a resistive element as part of a MEOL and/or FEOL process, in accordance with some embodiments. The method 1200 is described with reference to FIGS. 1-11. Thus, one or more aspects discussed above may also apply to the method 1200. It is understood that parts of the method 1200 and/or any of the exemplary transistor devices discussed with reference to the method 1200 may be fabricated by a well-known complementary metal-oxide-semiconductor (CMOS) technology process flow, and thus some processes are only briefly described herein. Also, additional steps may be performed before, after, and/or during the method 1200. Moreover, it is noted that the process steps of the method 1200, including any descriptions given with reference to the figures are merely exemplary and are not intended to be limiting beyond what is specifically recited in the claims that follow.

The method 1200 begins at block 1202 where a substrate including a plurality of dummy gate structures is provided. The substrate may be as described above with reference to the semiconductor device 200. In some embodiments, the plurality of dummy gate structures include a dummy gate dielectric and a dummy gate electrode (e.g., such as a polysilicon gate). In some examples, sidewall spacer layers (e.g., such as the sidewall spacers 210, 212) are formed on sidewalls of respective ones of the plurality of dummy gate structures. In various embodiments, source/drain features (e.g., such as the source/drain features 204, 204A, 204B, 204C, 204D) may be formed on one or both sides of a given dummy gate structure of the plurality of dummy gate structures. In at least some cases, there is no source/drain feature formed on one or both sides of a particular dummy gate structure of the plurality of dummy gate structures. In various embodiments, some of the dummy gate structures of the plurality of dummy gate structures are formed in active regions over fin elements extending from the substrate. Further, in some cases, some of the dummy gate structures of the plurality of dummy gate structures are formed along an active edge (e.g., along a boundary between an active region and an isolation region) that is free of fin elements.

The method 1200 proceeds to block 1204 where at least one dummy gate structure of the plurality of dummy gate structures is replaced with a resistive element. In some embodiments, a first one of the dummy gate structures of the plurality of dummy gate structures may be removed and replaced by high-K/metal gate structure (e.g., such as the gate structure 206), and a second one of the dummy gate structures of the plurality of dummy gate structures may be removed and replaced by a resistive element (e.g., such as the resistive element 208). As discussed above, the resistive element 208 may include a first resistive layer 208A and a second resistive layer 208B over the first resistive layer 208A. In some embodiments, the first resistive layer 208A includes TiN, related oxides such as TiOₓ or TiNOₓ, or combinations thereof. Thus, for example and in various embodiments, the first resistive layer 208A may include a single layer of TiN, a single oxide layer such as TiOₓ or TiNOₓ, or a stack of layers such as TiN/TiOₓ or TiN/TiNOₓ, as well as other combinations thereof. In some embodiments, the second resistive layer 208B includes crystalline silicon (Si), amorphous Si (a-Si), SiOₓ, a-SiOₓ, or combinations thereof. Thus, for example and in various embodiments, the second resistive layer 208B may include a single layer of Si, a single layer of a-Si, a single layer of SiOₓ, a single layer of a-SiOₓ, or a stack of layers such as Si/SiOₓ, a-Si/a-SiOₓ, as well as other combinations thereof. After replacing the dummy gate structures with high-K/metal gate structures and/or with resistive elements, the sidewall spacer layers (e.g., such as the sidewall spacers 210, 212) remain disposed on sidewalls of respective ones of the high-K/metal gate structures and the resistive elements.

In various examples, a source/drain feature is disposed between an adjacent high-K/metal gate structure and a resistive element (as in FIGS. 2, 6, 7). In some cases, the source/drain feature may be disposed on only one side of the resistive element (as in FIG. 2, 7). In some examples, there is no source/drain feature disposed between an adjacent high-K/metal gate structure and a resistive element (as in FIG. 5). In some embodiments, there is no source/drain feature disposed on either side of the resistive element (as in FIG. 5). In some cases, the source/drain feature may be disposed on both sides of the resistive element (as in FIG. 6).

The resistive element formed at block 1204 may have a variety of shapes in a top view, such as shown in the examples of FIGS. 1, 4A, 4B, and 4C. The resistive element may further have a variety of thicknesses to tune the total resistance of the resistive element, such as shown in the examples of FIGS. 3, 8, 9, and 10. Further, depending on whether the resistive element is formed in an active region with fin elements or along an active edge without fin elements, the resulting resistive element may have different cross-sectional configurations, such as shown in the examples of FIGS. 3, 8, 9, and 10.

The method 1200 proceeds to block 1206 where contacts to the resistive element are formed. Forming such contacts may include formation of dielectric layers such as ILD layers (e.g., such as ILD0, ILD1, ILD2), nitride layers, and a CESL, patterning of the dielectric layers to form openings, and deposition of metal layers, silicide layers, and/or adhesion layers to form contacts (e.g., such as first and second electrical contacts 402, 404) to the resistive element, to source/drain features, to high-K/metal gate structures, and in some cases to form contacts therebetween. Various exemplary configurations of the dielectric layers and metal layers, and contacts thus formed, have been given above with respect to FIGS. 2, 4A, 4B, 4C, 5, 6, 7, and 11. In some embodiments, the resistive elements may be configured to contact an adjacent source/drain feature (e.g., as in FIGS. 2, 6), an overlying BEOL layer (e.g., as in FIGS. 2, 5, 6, 7), or other feature of the semiconductor device. In some cases, the resistive element may be connected to a via rail (VDR).

The various embodiments described herein offer several advantages over the existing art. It will be understood that not all advantages have been necessarily discussed herein, no particular advantage is required for all embodiments, and other embodiments may offer different advantages. As one example, embodiments discussed herein include semiconductor structures having a resistive element, where the resistive element is formed as part of a MEOL and/or FEOL process. In contrast to at least some existing implementations where resistive elements are formed as part of a BEOL process, and in accordance with embodiments of the present disclosure, by forming the resistive element as part of a MEOL and/or FEOL process, consumption of valuable chip area can be reduced, particularly in the BEOL, and associated processing costs are also reduced. In addition, resistive elements formed in the MEOL and/or FEOL are disposed closer to FEOL devices (e.g., transistors), thereby decreasing resistance, decreasing signal delay, and enhancing device performance.

Thus, one of the embodiments of the present disclosure provides a semiconductor device including a substrate having an active region, a first gate structure formed over the active region, and a first resistive element formed over the active region and adjacent to the first gate structure. In some embodiments, the first resistive element includes a first resistive layer and a second resistive layer formed over the first resistive layer. In some examples, a total resistance of the first resistive element is a combination of resistances of the first and second resistive layers.

In another of the embodiments, discussed is a semiconductor device including an active region having a fin element and a resistive element formed over the fin element. In some embodiments, the resistive element includes a first resistive layer and a second resistive layer formed over the first resistive layer. In some examples, sidewall spacers are disposed on opposing sidewalls of the resistive element. In some embodiments, the semiconductor device further includes a first metal layer contacting an end of the resistive element.

In yet another of the embodiments, discussed is a method including providing a substrate having a plurality of dummy gate structures. In some embodiments, sidewall spacers are formed on sidewalls of respective ones of the plurality of dummy gate structures. In some examples, the method further includes replacing a first one of the dummy gate structures of the plurality of dummy gate structures with a high-K/metal gate structure. In some cases, the method further includes replacing a second one of the dummy gate structures of the plurality of dummy gate structures with a resistive element. In some embodiments, the resistive element includes a first resistive layer and a second resistive layer formed over the first resistive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate structure formed over the substrate; and
a first resistive element comprising a first metal formed over the substrate and adjacent to the gate structure; and
an interconnect feature comprising a second metal coupled to the first resistive element, wherein the first metal is different from the second metal.

2. The semiconductor device of claim 1, wherein the first resistive element is disposed over an active region.

3. The semiconductor device of claim 2, wherein the active region includes a fin element of a substantially uniform composition extending from the substrate or a plurality of stacked nanosheets disposed over the substrate.

4. The semiconductor device of claim 1, wherein the first metal includes Ti, Ta, or a combination thereof.

5. The semiconductor device of claim 1, wherein the second metal includes Cu, Co, W, Ru, or a combination thereof.

6. The semiconductor device of claim 2, further comprising:
an isolation region abutting the active region, wherein an active edge is defined along a boundary between the active region and the isolation region; and
a second resistive element formed along the active edge.

7. The semiconductor device of claim 6, wherein the second resistive element comprises the first metal.

8. The semiconductor device of claim 6, wherein the active edge is free of fin elements.

9. The semiconductor device of claim 2, further comprising:
a source/drain feature disposed over the active region, wherein the source/drain feature interposes the gate structure and the first resistive element.

10. A semiconductor device, comprising:
an active region including a nanostructure; and
a resistive element formed over the nanostructure, wherein the resistive element includes a first resistive layer and a second resistive layer formed over the first resistive layer, and wherein sidewall spacers are disposed on opposing sidewalls of the resistive element; and
a first metal layer contacting an end of the resistive element.

11. The semiconductor device of claim 10, wherein the first resistive layer includes TiN, TiOₓ, TiNOₓ, or combinations thereof.

12. The semiconductor device of claim 10, wherein the second resistive layer includes crystalline silicon (Si), amorphous Si (a-Si), SiOₓ, a-SiOₓ, or combinations thereof.

13. The semiconductor device of claim 10, wherein the first resistive layer has a sheet structure.

14. The semiconductor device of claim 10, wherein the first resistive layer has a thickness in a range of between about 0.1 nm-10 nm.

15. The semiconductor device of claim 10, wherein the resistive element has a linear rectangular prism shape from a top down view.

16. The semiconductor device of claim 10, wherein the resistive element has a curved rectangular prism shape from a top down view.

17. The semiconductor device of claim 10, further comprising:
a source/drain feature disposed over the active region; and
a gate structure formed over the active region;
wherein the source/drain feature interposes the resistive element and the gate structure.

18. The semiconductor device of claim 17, wherein a second metal layer contacts the source/drain feature, and wherein the first metal layer contacts the second metal layer.

19. A method, comprising:
providing a substrate including a plurality of dummy gate structures, wherein sidewall spacers are formed on sidewalls of respective ones of the plurality of dummy gate structures;
replacing a first one of the dummy gate structures of the plurality of dummy gate structures with a high-K/metal gate structure; and
replacing a second one of the dummy gate structures of the plurality of dummy gate structures with a resistive element, wherein the resistive element includes a first resistive layer and a second resistive layer formed over the first resistive layer.

20. The method of claim 19, further comprising:
forming a source/drain feature on one or both sides of the high-K/metal gate structure and the resistive element.
